(19) United States
(12) Patent Application Publication
(10) Pub. No.: US 2013/0029445 A1
(43) Pub. Date: Jan. 31, 2013

(54) METHOD OF MANUFACTURING SEMICONDUCTOR LIGHT EMITTING DEVICE

(71) Applicants: Gi Bum KIM, Hwaseong (KR); Won Goo HUR, Incheon (KR); Seung Woo CHOI, Seoul (KR); Seung Jae LEE, Cheonan (KR); Si Hyuk LEE, Anyang (KR); Tae Hun KIM, Anyang (KR)

(72) Inventors: Gi Bum KIM, Hwaseong (KR); Won Goo HUR, Incheon (KR); Seung Woo CHOI, Seoul (KR); Seung Jae LEE, Cheonan (KR); Si Hyuk LEE, Anyang (KR); Tae Hun KIM, Anyang (KR)

(73) Assignee: SAMSUNG ELECTRONICS CO., LTD.

(21) Appl. No.: 13/558,051

(22) Filed: Jul. 25, 2012

(30) Foreign Application Priority Data
Jul. 25, 2011 (KR) 10-2011-0073530

(51) Int. Cl. H01L 33/02

(52) U.S. Cl. 438/33; 257/E33.002

(57) ABSTRACT

There is provided a method of manufacturing a semiconductor light emitting device, the method including: preparing a substrate including first and second main surfaces opposing each other; forming a plurality of protruding parts in the first main surface of the substrate; forming a light emitting stack on the first main surface on which the plurality of protruding parts are formed; forming a plurality of light emitting structures by removing portions of the light emitting stack formed in regions corresponding to groove parts around the plurality of protruding parts; and separating the substrate along the groove parts.

### CROSS-REFERENCE TO RELATED APPLICATIONS

This application claims the priority of Korean Patent Application No. 10-2011-0073530 filed on Jul. 25, 2011, in the Korean Intellectual Property Office, the disclosure of which is incorporated herein by reference.

### BACKGROUND OF THE INVENTION

1. Field of the Invention

The present invention relates to a method of manufacturing a semiconductor light emitting device.

2. Description of the Related Art

Generally, a light emitting diode (LED) emits light by converting electrical signals into infrared rays, visible rays or ultraviolet rays, using the characteristics of compound semiconductors. The LED is a kind of electroluminescent (EL) device. An LED using a group III-V compound semiconductor is currently commercialized. A group III nitride-based compound semiconductor is a direct transition semiconductor, and can achieve a stable operation at a high temperature compared to other semiconductors, and thus the group III nitride-based compound semiconductor is widely used in light emitting devices such as LEDs or laser diodes (LDs).

Individual chips constituting light emitting devices may be implemented by growing semiconductor layers on a single wafer and separating the wafer into chip units through a cutting process. In this regard, the chip unit based separation process may use a scribing process using a cutting tip or a blade, a breaking process, a scribing process using a laser, etc. The scribing process using a laser can increase an operation speed compared to the related art operations, which may produce an effect of improving productivity, whereas a chip (an electrode or an active layer) is damaged, which may deteriorate characteristics of a semiconductor light emitting device. In a case in which a stealth laser is used in the scribing process a modified layer may prevent external light extraction.

### SUMMARY OF THE INVENTION

An aspect of the present invention provides a method of manufacturing a semiconductor light emitting device with enhanced light extraction efficiency through a simple process.

Another aspect of the present invention provides a method of manufacturing a semiconductor light emitting device capable of improving reliability of the semiconductor light emitting device.

Another aspect of the present invention provides a method of manufacturing a semiconductor light emitting device increasing net die per wafer.

According to an aspect of the present invention, there is provided a method of manufacturing a semiconductor light emitting device, the method including: preparing a substrate including first and second main surfaces opposing each other; forming a plurality of protruding parts in the first main surface of the substrate; forming a light emitting stack including a first conductivity type semiconductor layer, an active layer, and a second conductivity type semiconductor layer on the first main surface on which the plurality of protruding parts are formed; forming a plurality of light emitting structures by removing portions of the light emitting stack formed in regions corresponding to groove parts around the plurality of protruding parts; and separating the substrate along the groove parts so that individual semiconductor light emitting devices are obtained from the plurality of light emitting structures formed on the substrate.

The groove parts may be exposed to the outside in the removing of the portions of the light emitting stack formed in the regions corresponding to the groove parts around the plurality of protruding parts.

In the forming of the light emitting stack, at least portions of the groove parts may remain empty.

The groove parts may have widths between about 10 m and about 50 μm.

The method may further include filling at least portions of the groove parts with a filling material.

The filling material may be resin or metal.

The filling material may have a high selective etching ratio with respect to the substrate.

The method may further include removing a portion of the substrate from the second main surface to allow the filling material contained in the groove parts to be exposed to the outside.

In the separating of the substrate along the groove parts, the filling material exposed to the outside may be removed.

The removing of the filling material may be performed by wet etching.

The method may further include forming electrodes on the plurality of light emitting structures.

The method may further include forming unevenness patterns on surfaces of the plurality of protruding parts.

The light emitting stack may be grown on sides of recess portions of the unevenness patterns.

In the separating of the substrate along the groove parts, a portion of the substrate may be removed from the second main surface.

The method may further include attaching a support substrate to the first main surface after the removing of the portions of the light emitting stack formed in the regions corresponding to the groove parts.

The method may further include removing a portion of the substrate from the second main surface using a polishing process after the attaching of the support substrate.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 6 are schematic views illustrating a method of manufacturing a semiconductor light emitting device according to embodiments of the present invention; and

FIGS. 7A and 7B are graphs illustrating a light output of each of semiconductor light emitting devices manufactured according to embodiments of the present invention.

### DETAILED DESCRIPTION OF THE EMBODIMENTS

Embodiments of the present invention will now be described in detail with reference to the accompanying drawings.

This invention may, however, be embodied in many different forms and should not be construed as being limited to the exemplary embodiments set forth herein. Rather, these embodiments are provided so that this disclosure will be thorough and complete, and will fully convey the scope of the invention to those skilled in the art. In the drawings, the shapes and sizes of elements may be exaggerated for clarity, and like reference numerals denote the same or like elements.

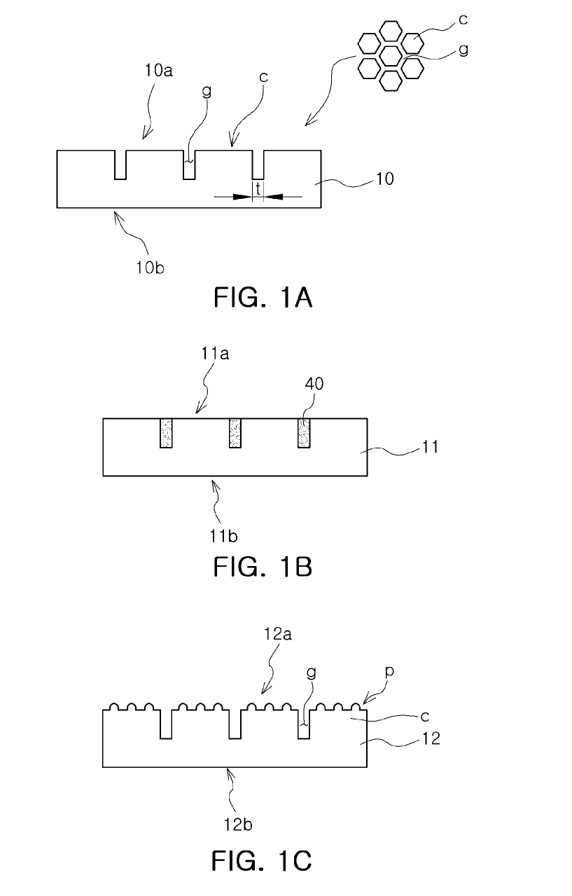

FIGS. 1A through 6 are schematic views illustrating a method of manufacturing a semiconductor light emitting device according to embodiments of the present invention.

Referring to FIG. 1A, a substrate 10 having first and second main surfaces 10a and 10b opposing each other may be prepared. A plurality of protruding parts c may be formed as columns in the first main surface 10a of the substrate 10. Although the protruding parts c in the present embodiment are formed as hexagonal columns in the first main surface 10a, they are not limited thereto, and the protruding parts c may be variously formed as tetragonal columns, pentagonal columns, cylindrical columns, or the like.

In the present embodiment, a single protruding part c may correspond to a unit region for the semiconductor light emitting device, and thus, semiconductor light emitting devices formed on the protruding parts c may have a shape corresponding thereto. In this case, the semiconductor light emitting device formed on the protruding part c is formed as a polygonal column or a cylindrical column, and thus a critical angle at an interface between air and the semiconductor light emitting device changes, thereby enhancing external light extraction efficiency. In particular, in a case in which the semiconductor light emitting device is formed as a hexagonal column as in the present embodiment, external light extraction efficiency may be enhanced according to the change in the critical angle, and at the same time, a space between devices on a wafer is minimized, thereby increasing net die per wafer.

The substrate 10 may be provided as a semiconductor growth substrate, and more specifically, may utilize a substrate formed of a material such as sapphire, SiC, MgAl₂O₄, MgO, LiAlO₂, LiGaO₂, GaN, or the like. In this case, sapphire having electrical insulation properties may most preferably be used. Sapphire is a crystal having Hexa-Rhombo R3C symmetry and has a lattice constant of 13.001 Å along a C-axis and a lattice constant of 4.758 Å along an A-axis. Orientation planes of the sapphire include a C (0001) plane, an A (1120) plane, an R (1102) plane, and the like. Particularly, the C plane is mainly used as a substrate for nitride growth because it relatively facilitates the growth of a nitride film and is stable at high temperatures.

The forming of the protruding parts c on the substrate 10 may be performed by forming groove parts g in the first main surface 10a of the substrate 10 by using a UV laser, a dicing process, a scribing process, or an etching process, which may be understood as forming the protruding parts c in the first main surface 10a of the substrate 10 in another aspect. Alternatively, as occasion demands, separate protruding parts may be formed on the first main surface 10a of the substrate 10.

The groove parts g may be formed in a chip unit separation region. The groove parts g may have depths between about 100 μm and about 170 μm and widths between about 10 μm and about 50 μm, without being limited thereto. In a case in which the groove parts g have a width t between about 10 μm and about 50 μm, at least portions of the groove parts g may remain empty even while semiconductor layers are stacked on the first main surface 10a of the substrate 10. As a result, air gaps may be formed in the groove parts g.

For example, the groove parts g may be formed by using a dry or wet etching process after forming a photo resist pattern having openings corresponding to regions in which the groove parts g are to be formed in the first main surface 10a of the substrate 10. The groove parts g may be formed in the entirety of the substrate 10 including an outer region thereof as well as a center region thereof in such a manner that a large number of devices can be manufactured on the substrate 10. In the case of using the dry etching process, a fluorine based gas such as CF₄, SF₆, or the like, a chlorine based gas such as Cl₂, BCl₃, or the like, argon (Ar) gas or the like may be used as an etching gas; however, without being limited thereto, various well-known etching gases may be used.

FIG. 1B is a schematic view illustrating a method of manufacturing a semiconductor light emitting device according to another embodiment of the present invention.

In the present embodiment, an operation of filling at least portions of the groove parts around the protruding parts in a first main surface 11a of a substrate 11 with a filling material 40 may be further included. The groove parts formed in the first main surface 11a may not be entirely filled with the filling material 40 and may only be partially filled therewith. Although a width of the groove parts is not particularly limited in the present embodiment, the groove parts may be formed to have as small a width as possible, thereby increasing net-die per wafer.

The filling material 40 may be resin or metal. Materials having excellent thermal stability in a semiconductor layer growth process such as MOCVD, MBE, HVPE, or the like may be used therefor. The filling material 40 may utilize materials having a high selective etching ratio with respect to the substrate 11 and semiconductor layers (not shown) formed on the top of the substrate 11. For example, synthetic resin including SiO₂, SiₓN_{y} or the like, a high melting point metal such as tungsten (W), titanium (Ti), and zinc (Zn) or the like, spin-on-glass (SOG), or the like may be used therefor.

Referring to FIG. 1C, an operation of forming an unevenness pattern p on the protruding parts c in a first main surface 12a of a substrate 12 may be further performed.

More specifically, the unevenness pattern p may be formed on the protruding parts c. In this regard, external light extraction efficiency may be enhanced by increasing a light scattering rate between the substrate 12 and a semiconductor layer (not shown) formed on the top of the substrate 12. Further, at least a portion of the unevenness pattern p is formed to have a curved surface as shown in FIG. 10, and thus the semiconductor layer formed on an upper surface of the unevenness pattern p grows on sides of recess portions of the unevenness pattern p, thereby preventing a dislocation defect from spreading upwardly. In consideration of the above-described light scattering effect and the prevention of spreading of the dislocation defect, a diameter of a bottom surface of a recess portion of the unevenness pattern p may be between 10 nm and 20 μm, a depth thereof may be between 10 nm and 10 μm, and a space between recess portions may be between 1 nm and 10 μm. In this regard, the term “diameter” is not intended to limit a shape of the bottom surface to a circular shape. The bottom surface of the recess portion may have various shapes. In this case, the bottom surface of the recess portion may have a width between 10 nm and 20 μm on average.

Meanwhile, FIG. 1C shows the unevenness pattern p is formed in a state in which the groove parts g are exposed to the outside, but the unevenness pattern p may be formed on the first main surface 12a of the substrate 12 after the filling of the groove parts with the filling material 40 as shown in FIG. 1B. However, the operation shown in FIG. 1C is not necessarily required in the present invention, and may be selectively employed as occasion demands.

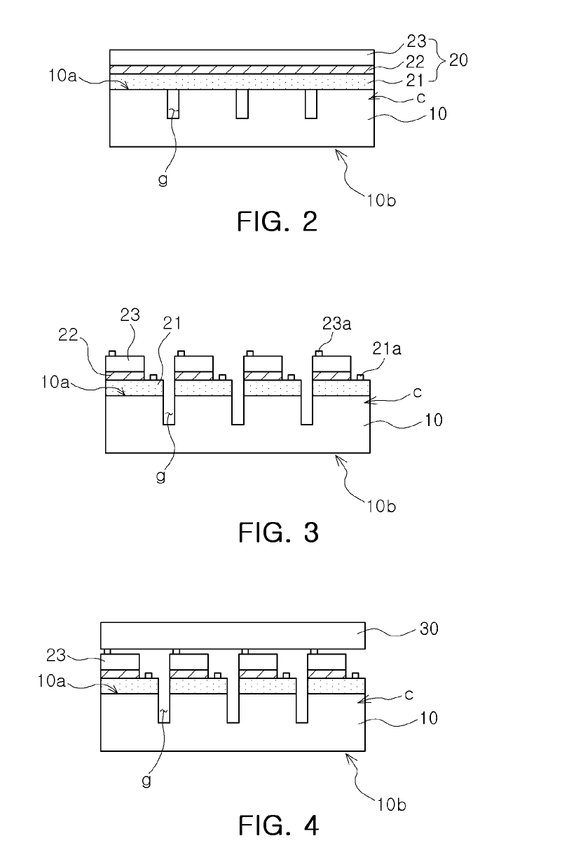

Next, as shown in FIG. 2, a light emitting stack 20, including a first conductivity type semiconductor layer 21, an active layer 22, and a second conductivity type semiconductor layer 23, may be formed on the substrate 10 having the protruding parts c formed in the first main surface 10a thereof by using a semiconductor layer growth process such as MOCVD, MBE, HVPE, or the like. Although not shown, to relieve lattice defects in the light emitting stack 20 grown on the substrate 10, a buffer layer (not shown) formed as an undoped semiconductor layer made of a nitride or the like may be interposed between the light emitting stack 20 and the substrate 10. In the present embodiment, when the light emitting stack 20 is formed on the substrate 10, at least portions of the groove parts g formed in the first main surface 10a of the substrate 10 may remain empty and form air gaps. Alternatively, as shown in FIG. 1B, the light emitting stack 20 may be formed on the top of the groove parts g that are filled with the filling material 40.

The first conductivity type semiconductor layer 21 and the second conductivity type semiconductor layer 23 included in the light emitting stack 20 may be n-type and p-type semiconductor layers, respectively, and may be formed of nitride semiconductors. Thus, first and second conductivity types in the present embodiment may be understood as n-type and p-type, respectively. The first and second conductivity type semiconductor layers 21 and 23 may have a compositional formula of AlₓIn_{y}Ga_{(1-x-y)}N (0≦x≦1, 0≦y≦1, and 0≦x+y≦1). For example, GaN, AlGaN, InGaN, or the like may be used. The active layer 22 formed between the first and second conductivity type semiconductor layers 21 and 23 may emit light having a predetermined amount of energy by recombination of electrons and holes, and may have a multi-quantum well (MQW) structure in which quantum well layers and quantum barrier layers are alternatively stacked. In the case of the MQW structure, for example, an InGaN/GaN structure may be used.

Next, as shown in FIG. 3, a plurality of light emitting structures may be formed by removing portions of the light emitting stack 20 formed in regions corresponding to the groove parts g around the protruding parts c. First and second electrodes 21a and 23a may be formed on each of the plurality of light emitting structures. The regions in which the groove parts g are formed may correspond to device separation regions. In a case in which the groove parts g formed in the first main surface 10a of the substrate 10 remain empty, the groove parts g may be exposed to the outside by removing portions of the light emitting stack 20. On the other hand, in a case in which the groove parts g are filled with the filling material 40, the filling material 40 may be exposed by removing portions of the light emitting stack 20 corresponding to the groove parts g.

The first and second electrodes 21a and 23a formed in each of the plurality of light emitting structures obtained by dividing the light emitting stack 20 may be formed of a material including any one of Au, Ni, Al, Cu, W, Si, Se, and GaAs, and may be formed by plating, sputtering, deposition, or the like. The first and second electrodes 21a and 23a may be electrically connected to the first and second conductivity type semiconductor layers 21 and 23, respectively, and may receive electrical signals from the outside. In the present embodiment, the first electrode 21a is formed on a portion of the first conductivity type semiconductor layer 21 exposed by removing portions of the second conductivity type semiconductor layer 23, the active layer 22, and the first conductivity type semiconductor layer 21; however, the number, shape, and location of the first electrode 21a may be modified in various ways.

Next, as shown in FIG. 4, a support substrate 30 may be provided above the first main surface 10a after removing portions of the light emitting stack 20 corresponding to the groove parts g around the protruding parts c. The support substrate 30 may serve as a support body for supporting the plurality of light emitting structures during a process of polishing the substrate 10 to be described later. A material for the support substrate 30 is not particularly limited. The support substrate 30 may be attached to top surfaces of the plurality of light emitting structures by using, for example, a bonding material (not shown) coated on glass or metal, or the like.

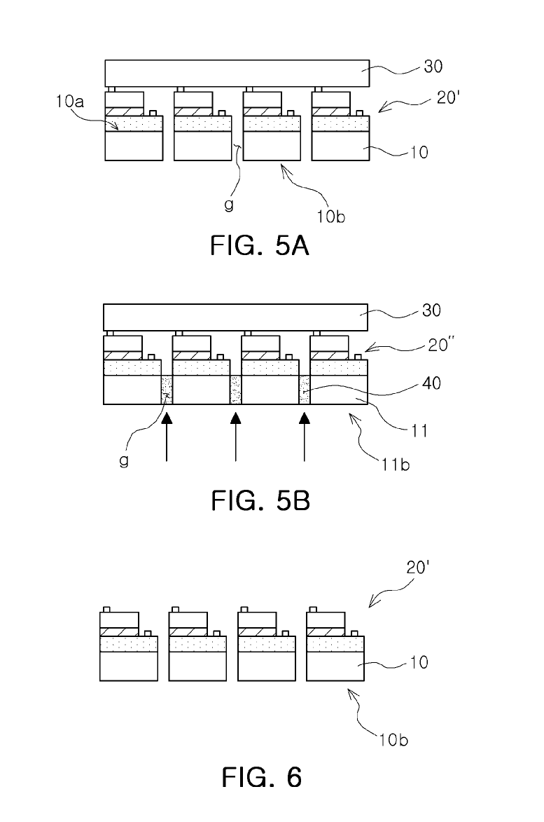

Next, referring to FIG. 5A, the substrate 10 may be separated along the groove parts g in such a manner that individual semiconductor light emitting devices 20′ can be obtained from the plurality of light emitting structures formed on the substrate 10. For example, the substrate 10 having the light emitting structures formed thereon may be divided into device units along the groove parts g by removing a portion of the substrate 10 from the second main surface 10b of the substrate 10. The portion of the substrate 10 may be removed by a polishing process such as lapping, grinding, polishing, or the like. Such a polishing process results in a reduction in the thickness of the substrate 10, and is performed until the groove parts g forming air gaps are exposed to the outside, and thus the plurality of light emitting structures formed on the substrate 10 may be divided into units of the individual semiconductor light emitting devices 20′ as shown in FIG. 5A.

In this case, the individual semiconductor light emitting devices 20′ may have shapes corresponding to the protruding parts c formed in the first main surface 10a of the substrate 10, i.e., hexagonal columns in the case of the present embodiment. However, a method of separating the substrate 10 along the groove parts g is not limited thereto, and the individual semiconductor light emitting devices 20′ may be obtained by applying a breaking or dicing process to the groove parts g.

Meanwhile, referring to FIG. 5B, in a case in which the filling material 40 is filled in the groove parts g, the filling material 40 may be exposed to the outside. To allow the filling material 40 to be exposed to the outside, the portion of the substrate 11 may be removed from the second main surface 11b of the substrate 11. However, in this case, a breaking or dicing process may be applied to the groove parts g of the substrate 11. The filling material 40 may utilize materials having a high selective etching ratio with respect to the substrate 11 and the light emitting structures formed on the top of the substrate 11. For example, resin including SiO₂, SiₓN_{y} or the like, a high melting point metal such as tungsten (W), titanium (Ti), and zinc (Zn) or the like, spin-on-glass (SOG), or the like may be used therefor. In the present embodiment, the substrate 11 is not completely separated even when the groove parts g are exposed; however, the filling material 40 is removed from the groove parts g, and thus the substrate 11 may be separated from the groove parts g, and the individual semiconductor light emitting devices 20″ may be obtained.

Since the filling material 40 filling the groove parts g has the high selective etching ratio with respect to the substrate 11 and the light emitting structure, of the removing of the filling material 40 from the groove parts exposed by removing the portion of the substrate 11 may be performed by a wet etching process using an etching solution. The etching solution may vary according to a type and thickness of the filling material 40. For example, an acid- or base-based chemical solution such as HF, HNO, KOH, or the like may be used.

Next, as shown in FIG. 6, the plurality of semiconductor light emitting devices 20′ may be manufactured by removing the support substrate 30 from the plurality of light emitting structures. In the method of manufacturing the semiconductor light emitting devices 20′ according to the present embodiment, the semiconductor light emitting devices 20′ may be manufactured on a wafer including a plurality of protruding parts on a first main surface thereof. In this regard, the protruding parts may correspond to individual unit regions for the respective semiconductor light emitting devices 20′. Meanwhile, although not specifically shown, before removing the support substrate 30, tape may be attached to the second main surface 10b of the substrate 10 in order to fix locations of the semiconductor light emitting devices 20′. Here, the tape may be polyethylene, PET, or the like, and a process of attaching the tape is not necessarily required but may be omitted as occasion demands.

According to an embodiment of the present invention, a plurality of protruding parts are formed as columns on a surface of a substrate, and a plurality of light emitting structures are formed on the surface of the substrate on which the protruding parts are formed, thereby manufacturing semiconductor light emitting devices having shapes corresponding to the protruding parts through a simplified process. In a case in which the semiconductor light emitting device is formed as a column having various surface angles, a critical angle at alight emitting surface of the semiconductor light emitting device changes to thereby reduce an amount of light totally internally reflected, whereby external light extraction efficiency may be enhanced. Further, in the present embodiment, a laser irradiation process may be omitted during a process of separating the light emitting structures formed on the wafer to individual chip units, which inhibits surfaces of the light emitting structures from being damaged due to the irradiation of the laser, whereby the reliability of the semiconductor light emitting devices may be improved.

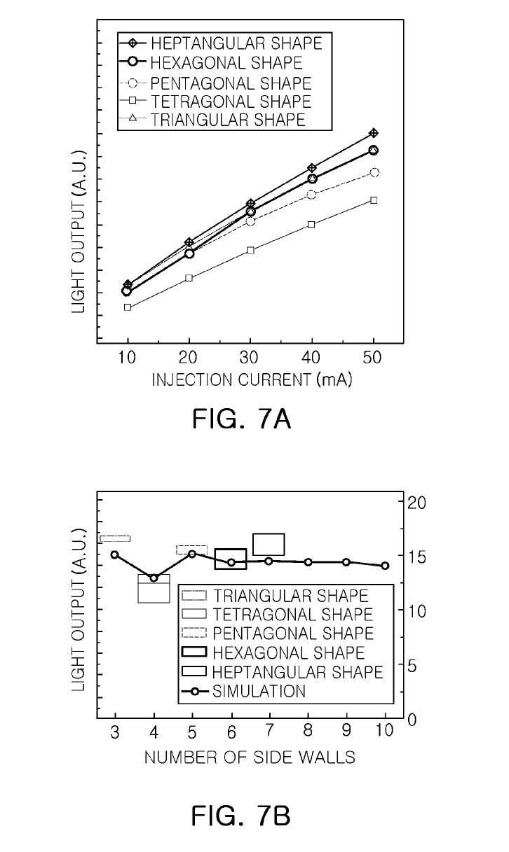

FIGS. 7A and 7B are graphs illustrating a light output from each of semiconductor light emitting devices manufactured according to embodiments of the present invention. More specifically, FIG. 7A is a graph illustrating variations in light output according to an increase in current injected into semiconductor light emitting devices having different shapes, and FIG. 7B is a graph illustrating variations in light output according to the number of surfaces forming side walls of semiconductor light emitting devices.

Referring to FIG. 7A, a semiconductor light emitting device having a top surface having a tetragonal shape has the lowest level of light output, irrespective of the injection current compared to semiconductor light emitting devices having top surfaces having triangular, pentagonal, hexagonal, and heptangular shapes. This is because light emitted from an active layer of a light emitting structure is incident below a critical angle at a surface of a chip having the tetragonal shape and has a relatively high rate of light that is totally reflected to the inside of the chip. When the chip is formed as a polygonal or cylindrical column other than a tetragonal column, the critical angle changes, and thus external light extraction efficiency may increase.

According to an embodiment of the present invention, light emitting structures are formed on a top surface of a semiconductor growth substrate including a plurality of protruding parts, and thus semiconductor light emitting devices having a shape corresponding to the protruding parts may be manufactured, thereby allowing for the manufacturing of the semiconductor light emitting devices with enhanced external light extraction efficiency by using a simple method. Further, a laser irradiation process used to separate the light emitting structures into chip units is omitted, which inhibits sides of the chip from being damaged due to the irradiation of the laser and prevents a characteristic deterioration of the semiconductor light emitting device. When a circular wafer is used, a region in which the light emitting structures are not formed is minimized, thereby increasing net die per wafer. More specifically, in a case in which a laser is used to separate the light emitting structures formed on the circular wafer into individual chip units having a tetragonal shape, most of a curve region adjacent to an outer region of the circular wafer is lost. However, in the present embodiment, the light emitting structures stacked on the entirety of a wafer including a plurality of protruding parts formed by groove parts are separated into individual chip units, thereby increasing net die of chips manufactured in a single wafer.

FIG. 7B shows light output according to the number of side walls of semiconductor light emitting devices and simulation results using the same. As shown in FIG. 7A, in a case in which the semiconductor light emitting devices have top surfaces having triangular, tetragonal, pentagonal, hexagonal, and heptangular shapes, the semiconductor light emitting device having the top surface having the tetragonal shape has the lowest light output, and as shown in FIG. 7B, the simulation result shows that a semiconductor light emitting device having seven or more side walls (the heptangular shape) may obtain higher light output than the semiconductor light emitting device having the top surface having the tetragonal shape. However, FIGS. 7A and 7B show that light emitting structures having various shapes such as polygonal columns or cylindrical columns may obtain an effect of enhancing external light extraction efficiency, which is intended to illustrate a method of easily and effectively manufacturing a light emitting structure with enhanced external light extraction efficiency according to an embodiment of the present invention, but is not intended to exclude the light emitting structure formed as the tetragonal column from the present invention.

As set forth above, according to embodiments of the invention, a method of manufacturing semiconductor light emitting devices with enhanced external light extraction efficiency may be provided by changing critical angles at sides (light emitting surfaces) of the light emitting devices because of various shapes.

According to embodiments of the present invention, a laser irradiation process may be skipped during a process for separating light emitting structures formed on a wafer into individual chip units, thereby inhibiting surfaces of the light emitting structures from being damaged due to the irradiation of a laser, whereby a method of manufacturing semiconductor light emitting devices with improved reliability may be provided.

According to embodiments of the present invention, light emitting structures are stacked on the entirety of a single wafer including a plurality of protruding parts formed by groove parts and are separated into individual chip units, thereby increasing net die of semiconductor light emitting devices manufactured on the wafer.

While the present invention has been shown and described in connection with the embodiments, it will be apparent to those skilled in the art that modifications and variations can be made without departing from the spirit and scope of the invention as defined by the appended claims.

What is claimed is:

1. A method of manufacturing a semiconductor light emitting device, the method comprising:
preparing a substrate including first and second main surfaces opposing each other;
forming a plurality of protruding parts in the first main surface of the substrate;
forming a light emitting stack including a first conductivity type semiconductor layer, an active layer, and a second conductivity type semiconductor layer on the first main surface on which the plurality of protruding parts are formed;
forming a plurality of light emitting structures by removing portions of the light emitting stack formed in regions corresponding to groove parts around the plurality of protruding parts; and
separating the substrate along the groove parts so that individual semiconductor light emitting devices are obtained from the plurality of light emitting structures formed on the substrate.

2. The method of claim 1, wherein the groove parts are exposed to the outside in the removing of the portions of the light emitting stack formed in the regions corresponding to the groove parts around the plurality of protruding parts.

3. The method of claim 1, wherein, in the forming of the light emitting stack, at least portions of the groove parts remain empty.

4. The method of claim 1, wherein the groove parts have widths between about 10 μm and about 50 μm.

5. The method of claim 1, further comprising filling at least portions of the groove parts with a filling material.

6. The method of claim 5, wherein the filling material is resin or metal.

7. The method of claim 5, wherein the filling material has a high selective etching ratio with respect to the substrate.

8. The method of claim 5, further comprising removing a portion of the substrate from the second main surface to allow the filling material contained in the groove parts to be exposed to the outside.

9. The method of claim 8, wherein, in the separating of the substrate along the groove parts, the filling material exposed to the outside is removed.

10. The method of claim 9, wherein the removing of the filling material is performed by wet etching.

11. The method of claim 1, further comprising forming electrodes on the plurality of light emitting structures.

12. The method of claim 1, further comprising forming unevenness patterns on surfaces of the plurality of protruding parts.

13. The method of claim 12, wherein the light emitting stack is grown on sides of recess portions of the unevenness patterns.

14. The method of claim 1, wherein, in the separating of the substrate along the groove parts, a portion of the substrate is removed from the second main surface.

15. The method of claim 1, further comprising attaching a support substrate to the first main surface after the removing of the portions of the light emitting stack formed in the regions corresponding to the groove parts.

16. The method of claim 15, further comprising removing a portion of the substrate from the second main surface using a polishing process after the attaching of the support substrate.
